(19) United States
(12) Patent Application Publication
(10) Pub. No.: US 2015/0060990 A1
(43) Pub. Date: Mar. 5, 2015

(54) TRANSISTORS, METHODS OF MANUFACTURING THE SAME, AND ELECTRONIC DEVICES INCLUDING THE TRANSISTORS

(71) Applicant: Samsung Electronics Co., Ltd., Suwon-Si (KR)

(72) Inventors: Sun-jae KIM, Seoul (KR); Tae-sang KIM, Seoul (KR); Myung-kwan RYU, Yongin-si (KR); Joon-seok PARK, Yongin-si (KR); Seok-jun SEO, Anyang-si (KR); Kyoung-seok SON, Seoul (KR); Seong-ho CHO, Gwacheon-si (KR)

(73) Assignee: Samsung Electronics Co., Ltd., Suwon-Si (KR)

(21) Appl. No.: 14/206,025

(22) Filed: Mar. 12, 2014

(30) Foreign Application Priority Data
Aug. 29, 2013 (KR) 10-2013-0103428

(51) Int. Cl. H01L 29/786; H01L 27/12; H01L 29/10

(52) U.S. Cl. CPC H01L 29/7869; H01L 29/1033; H01L 27/1225
USPC 257/324

(57) ABSTRACT

Provided are transistors, methods of manufacturing the same, and electronic devices including the transistors. A transistor includes a channel layer having a multi-layer structure having first and second layers, the first and second semiconductor layers including a plurality of elements having respective concentrations, and the first layer is disposed closer to a gate than the second layer. The second layer has a higher electrical resistance than the first layer as a result of a combination of the elements and of their respective concentrations. At least one of the first and second layers includes a semiconductor material including zinc, oxygen, and nitrogen. One of the first and second layers includes a semiconductor material including zinc fluoronitride. An oxygen content of the second layer is higher than an oxygen content of the first layer. A fluorine content of the second layer is higher than a fluorine content of the first layer.

### CROSS-REFERENCE TO RELATED APPLICATIONS

This application claims priority from Korean Patent Application No. 10-2013-0103428, filed on Aug. 29, 2013, in the Korean Intellectual Property Office, the disclosure of which is incorporated herein in its entirety by reference.

### BACKGROUND

1. Field

The present disclosure relates to transistors, methods of manufacturing the same, and/or electronic devices including the transistors.

2. Description of the Related Art

Transistors are widely used as switching devices or driving devices in electronic devices. In particular, since a thin film transistor (TFT) may be manufactured on a glass substrate or a plastic substrate, TFTs are used in display apparatuses such as organic light-emitting display apparatuses or liquid crystal display apparatuses. The performance of a TFT may mostly depend on properties of a channel layer (semiconductor layer).

Most commercially available display apparatuses use a TFT including a channel layer formed of amorphous silicon (hereinafter, referred to as an amorphous silicon TFT) or a TFT including a channel layer formed of polycrystalline silicon (hereinafter, referred to as a polycrystalline silicon TFT). An amorphous silicon TFT generally presents a disadvantage in that because the charge mobility of the TFT is about 0.5 cm²/Vs or so, which is a low charge mobility, it is difficult to increase an operating speed of a display apparatus. A polycrystalline silicon TFT also presents a disadvantage in that since crystallization, impurity doping, and activation processes are required, a manufacturing process is more complex and manufacturing costs are higher than manufacturing costs of an amorphous silicon TFT. Also, the polycrystalline silicon TFT presents a disadvantage in that, since it is difficult to ensure uniformity of a polycrystalline silicon layer, image quality is reduced when the polycrystalline silicon layer is used as a channel layer of a large-size display apparatus.

In order to realize a next generation high-performance/high-resolution/large-size display apparatus, a TFT having excellent performance may be preferred. In this regard, research has been conducted on an oxide TFT using an oxide semiconductor having a high carrier mobility as a material of a channel layer. However, manufacturing a transistor (TFT) that ensures excellent switching characteristics (ON/OFF characteristics) and high reliability as well as having high mobility is difficult.

### SUMMARY

Provided are transistors including a channel having a multi-layer structure, according to at least one example embodiment.

Provided are transistors having a high mobility and excellent switching characteristics, according to at least one example embodiment.

Provided are transistors having a low OFF current level, according to at least one example embodiment.

Provided are transistors having an adjusted threshold voltage, according to at least one example embodiment.

Provided are transistors which reliability is improved by reducing (or, alternatively, suppressing) degradation of a channel layer, according to at least one example embodiment.

Provided are methods of manufacturing the transistors, according to at least one example embodiment.

Provided are electronic devices (e.g., display apparatuses) including the transistors according to at least one example embodiment.

Additional example embodiments will be set forth in part in the description which follows and, in part, will be apparent from the description, or may be learned by practice of the presented embodiments.

According to an example embodiment, a transistor includes: a channel layer that has a multi-layer structure; a source and a drain that respectively contact first and second regions of the channel layer; a gate that corresponds to the channel layer; and a gate insulating layer that is disposed between the channel layer and the gate, wherein the channel layer includes first and second layers, wherein the first layer is disposed closer to the gate than the second layer, wherein the first and second layers include a semiconductor material including zinc, oxygen, and nitrogen; and wherein the second layer has an electrical resistance that is higher than an electrical resistance of the first layer.

An oxygen content of the second layer may be higher than an oxygen content of the first layer.

The second layer may further include fluorine.

The first layer may not include fluorine.

The first and second layers may further include fluorine, and a fluorine content of the second layer may be higher than a fluorine content of the first layer.

At least one of the first and second layers may further include an additional element X, and the additional element X may include at least one cation from among boron (B), aluminum (Al), gallium (Ga), indium (In), tin (Sn), titanium (Ti), zirconium (Zr), hafnium (Hf), and silicon (Si), at least one anion from among fluorine (F), chlorine (CI), bromine (Br), iodine (I), sulfur (S), and selenium (Se), or a combination thereof.

A content of the additional element X of the first layer and a content of the additional element X of the second layer may be different from each other.

The additional X included in the first layer and the additional element X included in the second layer may be the same.

The additional element X included in the first layer and the additional element X included in the second layer may be different from each other.

The second layer may be configured to reduce an OFF current of the transistor.

The second layer may be configured to increase a threshold voltage of the transistor in a positive (+) direction.

The gate may be disposed below the channel layer.

The transistor may further include an etch-stop layer that is disposed on the channel layer.

The gate may be disposed above the channel layer.

According to another example embodiment, a display apparatus includes the transistor.

The display apparatus may be an organic light-emitting display apparatus or a liquid crystal display apparatus.

The transistor may be used as a switching device or a driving device.

According to another example embodiment, a transistor includes: a channel layer that has a multi-layer structure; a source and a drain that respectively contact first and second regions of the channel layer; a gate that corresponds to the channel layer; and a gate insulating layer that is disposed between the channel layer and the gate, wherein the channel layer includes first and second layers, wherein the first layer is disposed closer to the gate than the second layer is; wherein at least one of the first and second layers is formed of a semiconductor material including zinc fluoronitride, and wherein the second layer has an electrical resistance that is higher than an electrical resistance of the first layer.

The first layer may include zinc fluoronitride, and the second layer may include one of zinc oxide, zinc oxynitride, and zinc fluorooxynitride.

Both of the first and second layers may include zinc fluoronitride, wherein a fluorine content of the second layer is higher than a fluorine content of the first layer.

An oxygen content of the second layer may be higher than an oxygen content of the first layer.

At least one of the first and second layers may further include an additional element X, and wherein the additional element X may include at least one cation from among boron (B), aluminum (Al), gallium (Ga), indium (In), tin (Sn), titanium (Ti), zirconium (Zr), hafnium (Hf), and silicon (Si), at least one anion from among fluorine (F), chlorine (CI), bromine (Br), iodine (I), sulfur (S), and selenium (Se), or a combination thereof.

A content of the additional element X of the first layer and a content of the additional element X of the second layer may be different from each other.

The additional element X included in the first layer and the additional element X included in the second layer may be the same.

The additional element X included in the first layer and the additional element X included in the second layer may be different from each other.

The second layer may be configured to reduce an OFF current of the transistor.

The second layer may be configured to increase a threshold voltage of the transistor in a positive (+) direction.

The gate may be disposed below the channel layer.

When the gate is disposed under the channel layer, the transistor may further include an etch-stop layer that is disposed on the channel layer.

The gate may be disposed above the channel layer.

According to another example embodiment, a display apparatus includes the transistor.

The display apparatus may be an organic light-emitting display apparatus or a liquid crystal display apparatus.

The transistor may be used as a switching device or a driving device. According to at least one example embodiment, a transistor includes a gate disposed on a substrate, a gate insulating layer disposed on the gate, a channel layer disposed on the gate insulating layer, the channel layer including at least a first semiconductor layer and a second semiconductor layer, the first and second semiconductor layers including at least one of a plurality of elements having respective concentrations, a source and a drain respectively contacting a first region and a second region of the channel layer. According to at least one example embodiment, a combination of the elements and of the respective concentrations of the elements result in an electrical resistance of the second semiconductor layer being greater than an electrical resistance of the first semiconductor layer

### BRIEF DESCRIPTION OF THE DRAWINGS

These and/or other example embodiments will become apparent and more readily appreciated from the following description of the example embodiments, taken in conjunction with the accompanying drawings of which:

FIG. 1 is a cross-sectional view illustrating a transistor according to an example embodiment;

FIG. 2 is a cross-sectional view illustrating a transistor according to another example embodiment;

FIG. 3 is a cross-sectional view illustrating a transistor according to another example embodiment;

FIG. 4 is a cross-sectional view illustrating a transistor according to another example embodiment;

FIG. 5 is a cross-sectional view illustrating a transistor according to another example embodiment;

FIG. 6 is a cross-sectional view illustrating a transistor according to another example embodiment;

FIGS. 7A through 7D are cross-sectional views for explaining a method of manufacturing a transistor, according to an example embodiment;

FIGS. 8A through 8E are cross-sectional views for explaining a method of manufacturing a transistor, according to another example embodiment;

FIG. 9 is a graph illustrating transfer characteristics of a transistor including a channel layer having a multi-layer structure, according to an example embodiment; and

FIG. 10 is a cross-sectional view illustrating an electronic device including a transistor, according to an example embodiment.

### DETAILED DESCRIPTION

Various example embodiments will now be described more fully with reference to the accompanying drawings in which example embodiments are shown.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items. Expressions such as “at least one of,” when preceding a list of elements, modify the entire list of elements and do not modify the individual elements of the list.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted regions. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Reference will now be made in detail to embodiments, examples of which are illustrated in the accompanying drawings. Widths and thicknesses of layers or regions illustrated in the drawings are exaggerated for clarity. The same reference numerals denote the same elements throughout.

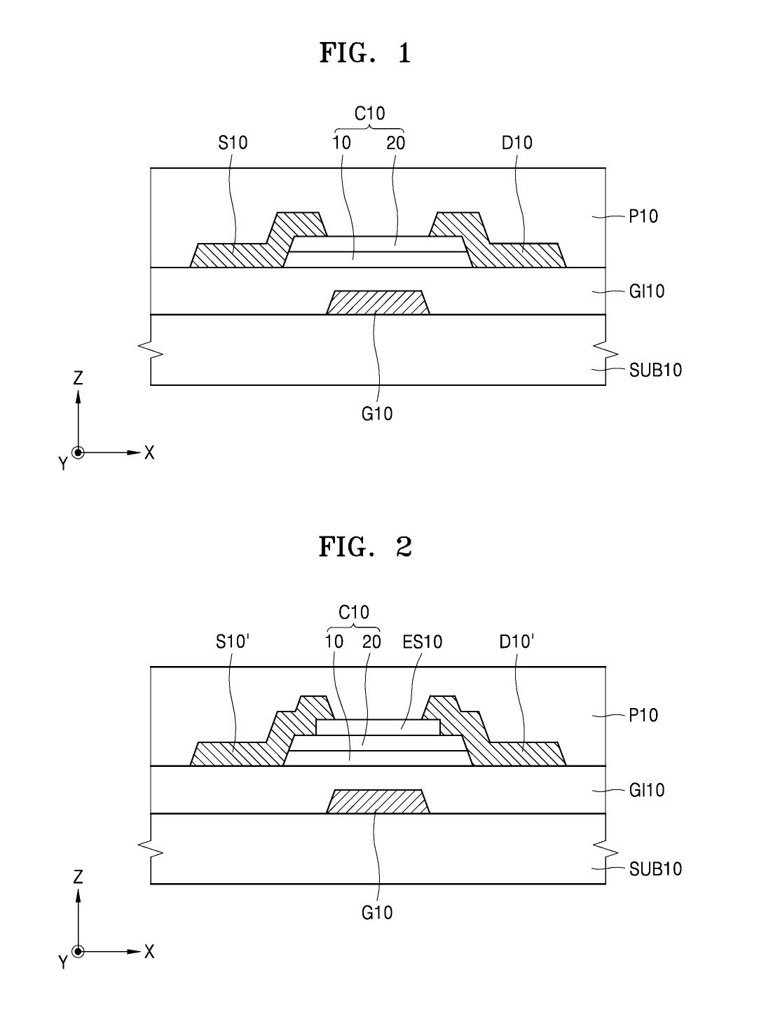

FIG. 1 is a cross-sectional view illustrating a transistor according to an example embodiment. The transistor of FIG. 1 is a thin film transistor (TFT) having a bottom gate structure in which a gate electrode G10 is disposed below (under) a channel layer C10.

Referring to FIG. 1, according to an example embodiment, the gate electrode G10 may be disposed on a substrate SUB10. The substrate SUB10 may be a glass substrate, or any one of various substrates used in a common semiconductor device process such as a plastic substrate or a silicon substrate. The gate electrode G10 may be formed of a general electrode material (e.g., a metal, an alloy, conductive metal oxide, conductive metal nitride, or the like). The gate electrode G10 may have a single-layer structure or a multi-layer structure. A gate insulating layer GI10 that covers the gate electrode G10 may be disposed on the substrate SUB10. The gate insulating layer GI10 may include a silicon oxide layer, a silicon oxynitride layer, or a silicon nitride layer, or may include another material layer, for example, a high-k material layer having a dielectric constant higher than the dielectric constant of a silicon nitride layer. The gate insulating layer GI10 may have a structure in which at least two of a silicon oxide layer, a silicon oxynitride layer, a silicon nitride layer, and a high-k material layer are stacked. In detail, the gate insulating layer GI10 may have a structure in which a silicon nitride layer and a silicon oxide layer are stacked, for example. In this case, the silicon nitride layer and the silicon oxide layer may be sequentially disposed on the gate electrode G10.

According to an example embodiment, the channel layer C10 may be disposed on the gate insulating layer GI10. The channel layer C10 may be disposed over the gate electrode G10 to face the gate electrode G10. A width of the channel layer C10 in an X-axis direction may be greater than a width of the gate electrode G10 in the X-axis direction. However, in some cases, a width of the channel layer C10 may be similar to or less than a width of the gate electrode G10. The channel layer C10 may have a multi-layer structure including at least two semiconductor layers. For example, the channel layer C10 may have a double-layer structure including a first semiconductor layer (hereinafter, referred to as a first layer) 10 and a second semiconductor layer (hereinafter, referred to as a second layer) 20. The first layer 10 that is disposed closer to the gate electrode G10 than the second layer 20 is may act as a main channel. The second layer 20 that is disposed farther away from the gate electrode G10 than the first layer 10 is may act as a sub-channel. The first layer 10 may be referred to as a front channel, and the second layer 20 may be referred to as a back channel. Materials and properties of the first layer 10 and the second layer 20 will be explained later in detail. The characteristics, performance, and reliability of the transistor may be improved due to the channel layer C10, which will be explained later in detail.

According to an example embodiment, a source electrode S10 and a drain electrode D10 that respectively contact first and second regions (for example, both ends) of the channel layer C10 may be disposed on the gate insulating layer GI10. Each of the source electrode S10 and the drain electrode D10 may have a single-layer structure or a multi-layer structure. Each of the source electrode S10 and the drain electrode D10 may be formed of a metal, an alloy, conductive metal oxide, conductive metal nitride, or the like. A material of each of the source electrode S10 and the drain electrode D10 may be the same as or similar to a material of the gate electrode G10. Each of the source electrode S10 and the drain electrode D10 may be formed of the same material as the gate electrode G10, or a different material than the gate electrode G10. Shapes and positions of the source electrode S10 and the drain electrode D10 may be changed.

According to an example embodiment, a passivation layer P10 that covers the channel layer C10, the source electrode S10, and the drain electrode D10 may be disposed on the gate insulating layer GI10. The passivation layer P10 may be a silicon oxide layer, a silicon oxynitride layer, a silicon nitride layer, or an organic layer, or may have a structure in which at least two of the silicon oxide layer, the silicon oxynitride layer, the silicon nitride layer, and the organic layer are stacked. For example, the passivation layer P10 may have a single-layer structure formed of silicon oxide or silicon nitride, or a multi-layer structure including a silicon oxide layer and a silicon nitride layer that is disposed on the silicon oxide layer. Also, the passivation layer P10 may have a multi-layer structure including three or more layers. In this case, the passivation layer P10 may include a silicon oxide layer, a silicon oxynitride layer, and a silicon nitride layer that are sequentially stacked. A configuration of the passivation layer P10 may be changed in various ways. Thicknesses of the gate electrode G10, the gate insulating layer GI10, the source electrode S10, the drain electrode D10, and the passivation layer P10 may respectively range from about 50 to about 300 nm, from about 50 to about 400 nm, from about 10 to about 200 nm, from about 10 to about 200 nm, and from about 50 to about 1200 nm. However, thickness ranges may be changed, if necessary.

Materials and properties of the first and second layers 10 and 20 of the channel layer C10 will now be explained in detail below.

According to an example embodiment, the first layer 10 may be formed of a first semiconductor material including zinc (Zn), oxygen (O), and nitrogen (N), and the second layer 20 may be formed of a second semiconductor material including zinc, oxygen, and nitrogen. An electrical resistance of the second layer 20 may be higher than an electrical resistance of the first layer 10. For example, the first layer 10 may include a zinc oxynitride (ZnON)-based semiconductor material, and the second layer 20 may also include a ZnON-based semiconductor material. In this case, an oxygen content of the second layer 20 may be higher than an oxygen content of the first layer 10. Due to such a difference in an oxygen content, the second layer 20 may have a higher electrical resistance than the first layer 10.

According to an example embodiment, when each of the first layer 10 and the second layer 20 includes a ZnON-based semiconductor, at least one of the first layer 10 and the second layer 20 may further include fluorine (F). For example, the second layer 20 may further include fluorine, and the first layer 10 may not include fluorine. In this case, the second layer 20 may include a zinc fluorooxynitride (ZnONF)-based semiconductor, and the first layer 10 may include a ZnON-based semiconductor. As such, when only the second layer 20 from among the first layer 10 and the second layer 20 includes fluorine, due to the fluorine, an electrical resistance of the second layer 20 may be increased to be higher than an electrical resistance of the first layer 10. Alternatively, both of the first layer 10 and the second layer 20 may include fluorine. That is, both of the first layer 10 and the second layer 20 may include a ZnONF-based semiconductor. In this case, a fluorine content of the second layer 20 may be higher than a fluorine content of the first layer 10. Due to such a difference in a fluorine content, the second layer 20 may have a higher electrical resistance than the first layer 10.

According to an example embodiment, when each of the first layer 10 and the second layer 20 includes a ZnON-based semiconductor, at least one of the first layer 10 and the second layer 20 may further include an additional element X. The additional element X may include at least one cation from among boron (B), aluminum (Al), gallium (Ga), indium (In), tin (Sn), titanium (Ti), zirconium (Zr), hafnium (Hf), and silicon (Si), at least one anion from among fluorine (F), chlorine (CI), bromine (Br), iodine (I), sulfur (S), and selenium (Se), or a combination of the at least one cation and the at least one anion. A content (content ratio) of the additional element X of the first layer 10 and a content (content ratio) of the additional element X of the second layer 20 may be different from each other. Electrical resistances of the first layer 10 and the second layer 20 may be controlled by a content (content ratio) of the additional element X. For example, as an aluminum content of the second layer 20 increases, an electrical resistance of the second layer 20 may increase. Accordingly, an electrical resistance of the second layer 20 may be increased to be higher than an electrical resistance of the first layer 10 by selectively adding aluminum only to the second layer 20 or by increasing an aluminum content of the second layer 20 to be higher than an aluminum content of the first layer 10. Also, when both the first layer 10 and the second layer 20 include the additional element X, the additional element X of the first layer 10 and the additional element X of the second layer 20 may be the same or different from each other. That is, the first layer 10 and the second layer 20 may include the same additional element X or different additional elements X. Electrical resistances of the first layer 10 and the second layer 20 may be controlled by a type of the additional element X as well as a content (content ratio) of the additional element X.

Alternatively, according to an example embodiment, at least one of the first layer 10 and the second layer 20 may be formed of a semiconductor material including zinc fluoronitride (ZnNF). Here, the second layer 20 may have a higher electrical resistance than the first layer 10. For example, the first layer 10 may include ZnNF, and the second layer 20 may include any one of zinc oxide (ZnO), ZnON, and ZnONF. In this case, the second layer 20 may be formed of a material (compound) including oxygen, and the first layer 10 may not include oxygen or may include little oxygen. Accordingly, an oxygen content of the second layer 20 may be higher than an oxygen content of the first layer 10. In this regard, an electrical resistance of the second layer 20 may be higher than an electrical resistance of the first layer 10. Alternatively, both of the first layer 10 and the second layer 20 may be formed of a semiconductor material including ZnNF. In this case, a fluorine content of the second layer 20 may be higher than a fluorine content of the first layer 10. Due to such a difference in a fluorine content, the second layer 20 may have a higher electrical resistance than the first layer 10.

According to an example embodiment, when at least one of the first layer 10 and the second layer 20 is formed of a semiconductor material including ZnNF, at least one of the first layer 10 and the second layer 20 may further include an additional element X. The additional element X may include at least one cation from among B, Al, Ga, In, Sn, Ti, Zr, Hf, and Si, at least one anion from among F, Cl, Br, I, S, and Se, or a combination of the at least one cation and the at least one anion. However, when the first layer 10 and/or the second layer 20 already includes fluorine, fluorine may be excluded from examples of the additional element X. A content (content ratio) of the additional element X of the first layer 10 and a content (content ratio) of the additional element X of the second layer 20 may be different from each other. Electrical resistances of the first layer 10 and the second layer 20 may be controlled by a content (content ratio) of the additional element X. For example, as a content (content ratio) of aluminum of the second layer 20 increases, an electrical resistance of the second layer 20 may increase. Also, when both the first layer 10 and the second layer 20 include the additional element X, the additional element X of the first layer 10 and the additional element X of the second layer 20 may be the same or different from each other. Electrical resistances of the first layer 10 and the second layer 20 may be controlled by a type of the additional element X as well as a content (content ratio) of the additional element X.

As described above, according to an example embodiment, an electrical resistance of the second layer 20 may be higher than an electrical resistance of the first layer 10. In other words, an electrical conductivity of the second layer 20 may be lower than an electrical conductivity of the first layer 10. Also, a carrier density of the second layer 20 may be lower than a carrier density of the first layer 10. A Hall mobility of the second layer 20 may be lower than a Hall mobility of the first layer 10. A leakage current in an OFF state may be reduced (or, alternatively, suppressed) by increasing an electrical resistance of the second layer 20 that is disposed far away from the gate electrode G10, and thus an OFF current level of the transistor may be reduced. In other words, when the second layer 20 that is a back channel region has a relatively high electrical resistance, an OFF current through the back channel region may be reduced or, alternatively, suppressed (prevented). If an OFF current level of the transistor is reduced, various effects may be obtained. Assuming that a display apparatus using a transistor having a high OFF current is manufactured, when a panel is driven, it may be difficult to express a gray scale due to a leakage current and it may difficult to maintain a node potential. However, according to the present example embodiment, since an OFF current level of the transistor may be reduced, when the transistor is applied to a display apparatus, a grayscale may be effectively expressed and switching characteristics may be improved.

According to an example embodiment, a threshold voltage of the transistor may shift in a positive (+) direction due to the second layer 20 having a relatively high electrical resistance. When a threshold voltage of the transistor has a high value in a negative (−) direction (that is, a high negative value), a voltage (an absolute value) of an input signal may be increased, and thus power consumption may be increased. However, according to the present example embodiment, since a threshold voltage of the transistor increases in a positive (+) direction due to the second layer 20, the transistor may be easily operated and power consumption may be reduced.

Also, in the present example embodiment, the first channel 10 that is a main channel may be protected by the second layer 20. When the transistor is manufactured, the channel layer C10 may be exposed during a plasma process or a wet process, and thus characteristics of the channel layer C10 may be changed or degraded. In particular, when a ZnON or ZnNF-based semiconductor is used, characteristics may be easily degraded during a plasma process or a wet process, thereby reducing the reliability of the transistor including the semiconductor. However, according to the present example embodiment, since the second layer 20 that has a relatively high electrical resistance and has a high resistance against plasma or a wet process is disposed on the first layer 10, the first layer 10 that is a main channel layer may be prevented from being degraded, thereby improving the reliability of the transistor. Also, when the second layer 20 is disposed on the first layer 10, the transistor may be manufactured without forming an etch-stop layer for protecting the channel layer C10. In this case, a process may be simplified.

According to an example embodiment, the reliability of the transistor with regard to a negative bias stress may be improved due to the second layer 20. As a hole concentration of a channel layer increases, the reliability of a transistor with regard to a negative bias stress may be reduced. In the present example embodiment, however, since a hole concentration of the second layer 20 may be reduced due to oxygen or fluorine, a hole concentration of the second layer 20 may be lower than a hole concentration of the first layer 10. Accordingly, the reliability of the transistor with regard to a negative bias stress may be improved due to the second layer 20.

According to an example embodiment, the transistor of the present example embodiment may have a high field-effect mobility due to the first layer 10 that has a relatively low electrical resistance and a high Hall mobility. Accordingly, the transistor may have a high mobility (high field-effect mobility), a low OFF current, and high reliability.

According to an example embodiment, a TFT including an oxynitride (e.g., ZnON) channel layer having a single-layer structure may have problems in that an OFF current is relatively high, a threshold voltage has a high negative value, and characteristics of the channel layer are easily degraded. Also, since the oxynitride channel layer has a high hole concentration, the TFT including the oxynitride channel layer having the single-layer structure may have low reliability with respect to a negative bias voltage. However, according to the present example embodiment, since the channel layer C10 having a multi-layer structure including two or more layers is used, the transistor may avoid the afore-described problems, and have excellent performance and high reliability.

According to an example embodiment, a semiconductor material of the channel layer C10 may include an amorphous phase, a crystalline phase, or a combination thereof. Also, the semiconductor material may have a plurality of nanocrystals (nanocrystalline phase) in an amorphous matrix. A thickness of the channel layer C10 may range from about 5 to about 300 nm, for example, from about 10 to about 200 nm. A thickness of the first layer 10 that is a main channel may range from about 5 to about 100 nm. A thickness of the second layer 20 that is a sub-channel may range from about 5 to about 100 nm. However, thickness ranges of the first layer 10 and the second layer 20 and a total thickness range of the channel layer C10 may be changed.

Additionally, in each of ZnON, ZnONF, and ZnNF used herein, only elements are listed and a composition ratio of the elements is neglected. For example, the term ‘ZnON’ used herein represents a material (compound) composed of zinc, oxygen, and nitrogen of various possible relative compositions. The same principle applies to ZnONF, and ZnNF. Also, since ZnON, ZnONF, or ZnNF may be a “compound” or a “material including a compound”, the ZnON, ZnONF, or ZnNF may be referred to as a compound semiconductor material or a semiconductor material including a compound. Accordingly, the terms “compound semiconductor material” and “semiconductor material including a compound” used herein are to be interpreted broadly.

Alternatively, the transistor of FIG. 1 may further include an etch-stop layer ES10 that is disposed on the channel layer C10, as shown in FIG. 2.

Referring to FIG. 2, according to an example embodiment, the etch-stop layer ES10 may be further disposed on the channel layer C10. A width of the etch-stop layer ES10 in an X-axis direction may be less than a width of the channel layer C10. Both ends of the channel layer C10 may not be covered by the etch-stop layer ES10. A source electrode S10′ may cover one end of each of the channel layer C10 and the etch-stop layer ES10, and a drain electrode D10′ may cover the other end of each of the channel layer C10 and the etch-stop layer ES10. The etch-stop layer ES10 may prevent the channel layer C10 from being damaged in an etching process for forming the source electrode S10′ and the drain electrode D10′. The etch-stop layer ES10 may include, for example, silicon oxide, silicon oxynitride, silicon nitride, or an organic insulating material. Whether to use the etch-stop layer ES10 may be determined according to a material of the channel layer C10 and materials of the source electrode S10′ and the drain electrode D10′. Alternatively, whether to use the etch-stop layer ES10 may be determined according to an etching process for forming the source electrode S10′ and the drain electrode D10′. Except for the etch-stop layer ES10 and shapes of the source/drain electrodes S10′ and D10′, a structure of the transistor FIG. 2 may be the same as or similar to a structure of the transistor of FIG. 1.

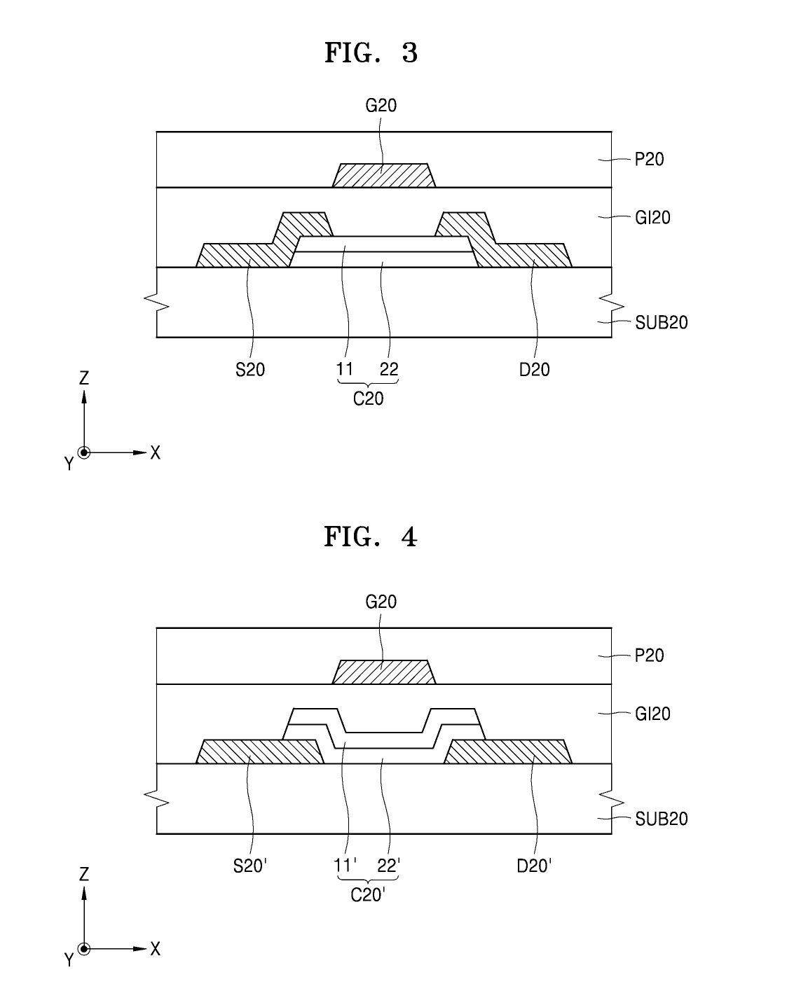

FIG. 3 is a cross-sectional view illustrating a transistor according to another example embodiment. The transistor of FIG. 3 is a TFT having a top gate structure in which a gate electrode G20 is disposed above (over) a channel layer C20.

Referring to FIG. 3, the channel layer C20 may be disposed on a substrate SUB20. The channel layer X20 may have an inverted structure obtained by inverting the channel layer C10 of FIG. 1 or a structure similar to the inverted structure. That is, the channel layer C20 of FIG. 3 may have a structure in which a second layer 22 equivalent to the second layer 20 and a first layer 11 equivalent to the first layer 10 of FIG. 1 are sequentially stacked on the substrate SUB20. That is, the channel layer C20 may have a structure in which the second layer 22 and the first layer 11 are sequentially stacked from the bottom. Materials, configurations, and characteristics of the first layer 11 and the second layer 22 may be the same as or similar to the materials, configurations and characteristics of the first layer 10 and the second layer 20 of FIG. 1, and thus a detailed explanation thereof will not be given. A source electrode S20 and a drain electrode D20 that respectively contact first and second regions (for example, both ends) of the channel layer C20 may be disposed on the substrate SUB20. A gate insulating layer GI20 that covers the channel layer C20, the source electrode S20, and the drain electrode D20 may be disposed on the substrate SUB20. The gate electrode G20 may be disposed on the gate insulating layer GI20. The gate electrode G20 may be disposed above (over) the channel layer C20. A passivation layer P20 that covers the gate electrode G20 may be disposed on the gate insulating layer GI20. Materials, structures, and thicknesses of the substrate SUB20, the source electrode S20, the drain electrode D20, the gate insulating layer GI20, the gate electrode G20, and the passivation layer P20 of FIG. 3 may be the same as or similar to the materials, structures and thicknesses of the substrate SUB10, the source electrode S10, the drain electrode D10, the gate insulating layer GI10, the gate electrode G10, and the passivation layer P10 of FIG.

According to an example embodiment, positions of the channel layer C20, and the source electrode S20 and the drain electrode D20 in FIG. 3 may be changed, as shown in FIG. 4.

Referring to FIG. 4, a source electrode S20′ and a drain electrode D20′ that are spaced apart from each other may be disposed on the substrate SUB20. A channel layer C20′ that contacts the source electrode S20′ and the drain electrode D20′ may be disposed on the substrate SUB20 between the source electrode S20′ and the drain electrode D20′. Hence, the source electrode S20′ and the drain electrode D20′ may contact both ends of a bottom surface of the channel layer C20′. The channel layer C20′ may have a structure in which a second layer 22′ and a first layer 11′ are stacked. The first layer 11′ and the second layer 22′ may be respectively formed of the same materials as the materials of the first layer 11 and the second layer 22 of FIG. 3. Except for the positions and shapes of the channel layer C20′, the source electrode S20′, and the drain electrode D20′, a structure of the transistor of FIG. 4 may be the same as a structure of the transistor of FIG. 3.

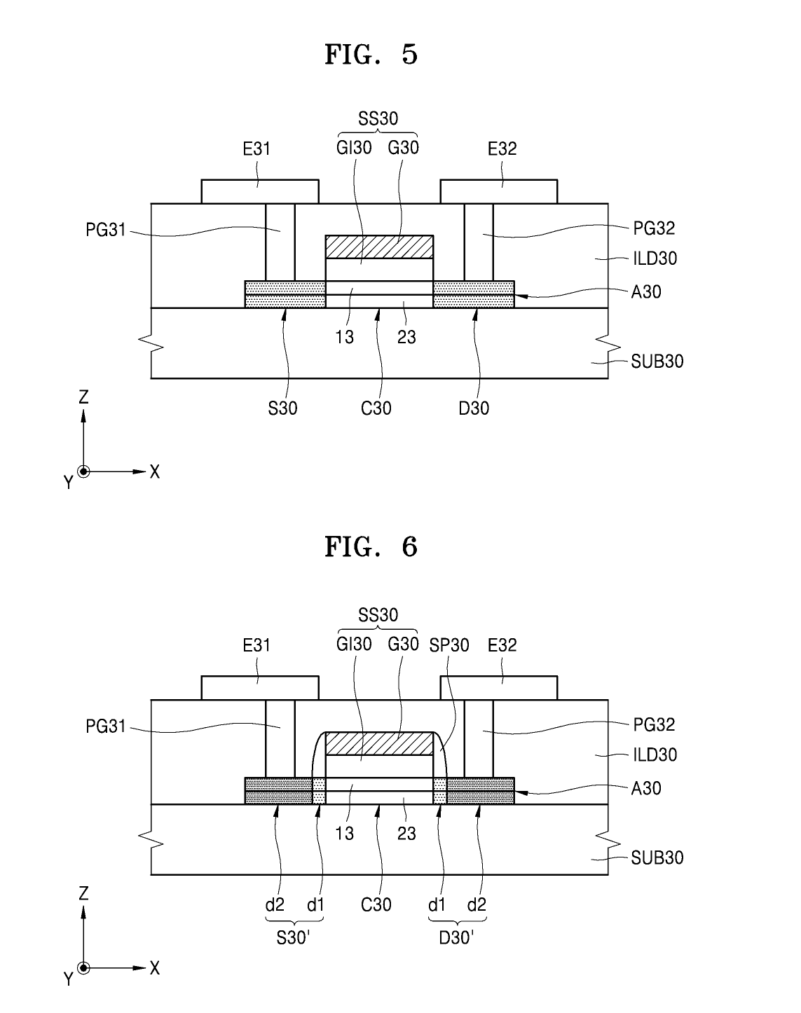

FIG. 5 is a cross-sectional view illustrating a transistor according to another example embodiment. The transistor of FIG. 5 is a TFT having a top gate structure in which a gate electrode G30 is disposed above a channel region C30.

Referring to FIG. 5, according to an example embodiment, an active layer A30 may be disposed on a substrate SUB30. The substrate SUB30 may be a glass substrate, or any of various substrates used in a common semiconductor device process such as a plastic substrate or a silicon substrate. The active layer A30 may be formed of a semiconductor material, and may have a multi-layer structure including two or more layers. For example, the active layer A30 may include a first semiconductor layer (hereinafter, referred to as a first layer) 13 and a second semiconductor layer (hereinafter, referred to as a second layer) 23. The first layer 13 may be disposed on the second layer 23. The active layer A30 may have the channel region C30 at or around a central portion thereof. In the channel region C30, materials and properties of the first layer 13 and the second layer 23 may be the same as or similar to the materials and properties of the first layer 10 and the second layer 23 of FIG. 1. In other words, in the channel region C30, a material and properties of the first layer 13 may be the same as or similar to the materials and properties of the first layer 10 of FIG. 1, and a material and properties of the second layer 23 may be the same as or similar to the materials and properties of the second layer 20 of FIG. 1.

According to an example embodiment, a stacked structure SS30 in which a gate insulating layer GI30 and the gate electrode G30 are sequentially stacked may be disposed on the channel region C30 of the active layer A30. A source region S30 and a drain region D30 may be disposed in the active layer A30 at both sides of the stacked structure SS30. Each of the source region S30 and the drain region D30 may have a higher electrical conductivity than the channel region C30. The source region S30 and the drain region D30 may be conductive regions. The source region S30 and the drain region D30 may be regions treated (processed) with plasma. For example, the source region S30 and the drain region D30 may be regions treated (processed) with plasma including hydrogen (H). When the active layer A30 on both sides of the stacked structure SS30 is treated (processed) with plasma of a gas including hydrogen, the source region S30 and the drain region D30 having conductive property may be formed. In this case, the gas including the hydrogen may be NH₃, H₂, SiH₄, or the like. When both end portions of the active layer A30 are treated (processed) with the plasma of the gas including the hydrogen, the hydrogen may act as a carrier by entering the active layer A30. Also, the plasma of the hydrogen may remove an anion (oxygen or the like) of the active layer A30, and thus an electrical conductivity of a plasma-treated region may be increased. Thus, the source region S30 and the drain region D30 may each include a region whose anion (oxygen or the like) concentration is relatively low. In other words, the source region S30 and the drain region D30 may each include a region whose cation concentration is relatively high, for example, a zinc-rich region.

According to an example embodiment, an interlayer insulating layer ILD30 that covers the gate electrode G30, the source region S30, and the drain region D30 may be disposed on the substrate SUB30. First and second electrodes E31 and E32 that are respectively electrically connected to the source region S30 and the drain region D30 may be disposed on the interlayer insulating layer ILD30. The source region S30 and the first electrode E31 may be connected to each other through a first conductive plug PG31, and the drain region D30 and the second electrode E32 may be connected to each other through a second conductive plug PG32. The first and second electrodes E31 and E32 may be respectively referred to as a source electrode and a drain electrode. Alternatively, the source region S30 and the drain region D30 themselves may be referred to as a source electrode and a drain electrode. A passivation layer (not shown) that covers the first and second electrodes E31 and E32 may be further disposed on the interlayer insulating layer ILD30.

According to an example embodiment, the transistor of FIG. 5 may have a self-aligned top gate structure in which positions of the source and drain regions S30 and D30 on both sides of the gate electrode G30 are determined (for example, automatically determined) by a position of the gate electrode G30. In this case, the source region S30 and the drain region D30 may not overlap with the gate electrode G30. The self-aligned top gate structure may be advantageous in scaling down a device (transistor) and increasing an operating speed. In particular, since a parasitic capacitance may be reduced, resistance-capacitance (RC) delay may be reduced (or, alternatively, suppressed), and thus an operating speed may be increased.

FIG. 6 is a cross-sectional view illustrating a transistor according to another example embodiment. FIG. 6 is a modification of FIG. 5 in that an insulating spacer SP30 is disposed on both side walls of the stacked structure SS30, and modified source/drain regions S30′ and D30′ are provided.

Referring to FIG. 6, the insulating spacers SP30 may be disposed on both side walls of the stacked structure SS30, according to an example embodiment. The source region S30′ and the drain region D30′ may be disposed in the active layer A30 on both sides of the stacked structure SS30. Each of the source region S30′ and the drain region D30′ may include two regions (hereinafter, referred to as first and second conductive regions) d1 and d2 having different electrical conductivities. The first conductive region d1 may be disposed adjacent to the channel region C30, that is, under each of the insulating spacers SP30. An electrical conductivity of the first conductive region d1 may be lower than an electrical conductivity of the second conductive region d2. The first conductive region d1 may be a region similar to a lightly doped drain (LDD) region. The source region S30′ and the drain region D30′ may be regions that are treated with plasma. A plasma treating time or number of the first conductive region d1 may be less than a plasma treating time or number of the second conductive region d2.

Methods of manufacturing transistors according to example embodiments will now be explained below.

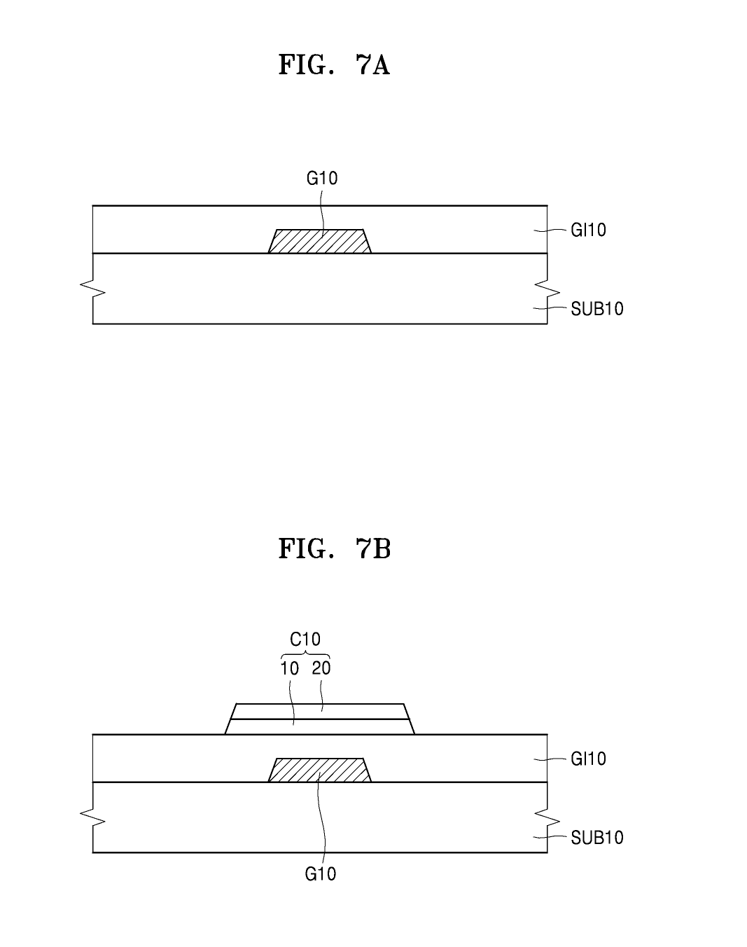

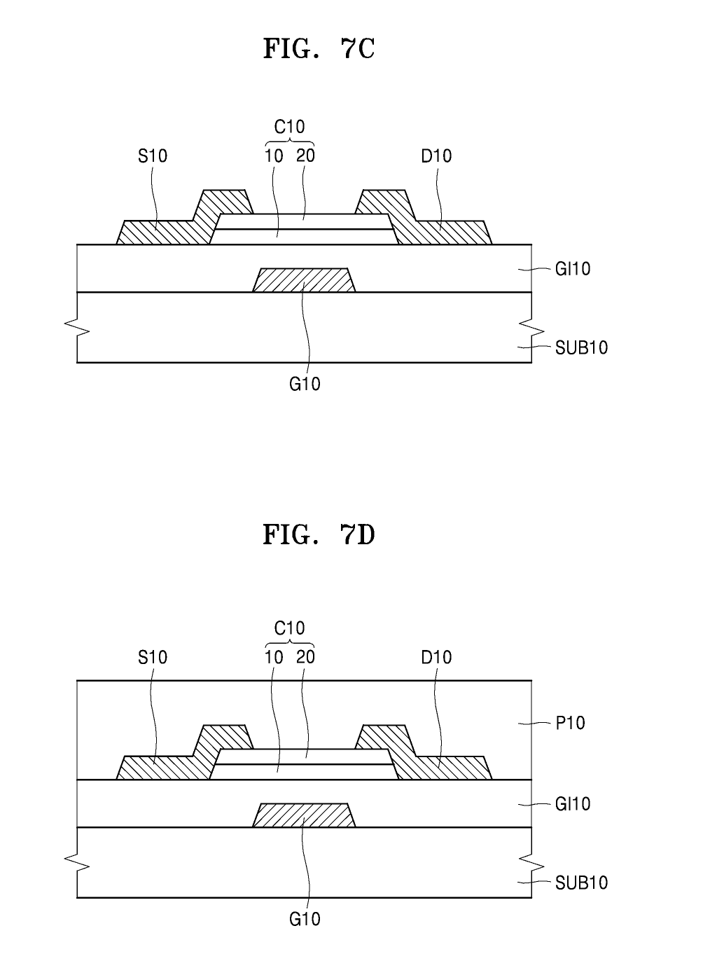

FIGS. 7A through 7D are cross-sectional views for explaining a method of manufacturing a transistor, according to an example embodiment of the present invention. The method of FIGS. 7A through 7D is a method of manufacturing a TFT having a bottom gate structure.

Referring to FIG. 7A, a gate electrode G10 may be formed on a substrate SUB10, and a gate insulating layer GI10 that covers the gate electrode G10 may be formed, according to an example embodiment. The substrate SUB10 may be a glass substrate, or any one of various substrates used in a common semiconductor device process such as a plastic substrate or a silicon substrate. The gate electrode G10 may be formed of a general electrode material (e.g., a metal, an alloy, conductive metal oxide, conductive metal nitride, or the like). The gate electrode G10 may be formed to have a single-layer structure or a multi-layer structure. The gate insulating layer GI10 may be formed of silicon oxide, silicon oxynitride, or silicon nitride, or may be formed of another material, for example, a high-k material having a dielectric constant higher than the dielectric constant of silicon nitride. The gate insulating layer GI10 may be formed to have a structure in which at least two of a silicon oxide layer, a silicon oxynitride layer, a silicon nitride layer, and a high-k material layer are stacked. In detail, the gate insulating layer GI10 may be formed to have a structure in which a silicon nitride layer and a silicon oxide layer are stacked, for example. In this case, the gate insulating layer GI10 may be formed by sequentially stacking the silicon nitride layer and the silicon oxide layer on the gate electrode G10.

Referring to FIG. 7B, a channel layer C10 may be formed on the gate insulating layer GI10, according to an example embodiment. The channel layer C10 may be formed of a semiconductor, and may be formed to have a multi-layer structure including two or more layers. For example, the channel layer C10 may be formed to have a double-layer structure including a first semiconductor layer (hereinafter, referred to as the first layer) 10 and a second semiconductor layer (hereinafter, referred to as the second layer) 20. Materials and properties of the first layer 10 and the second layer 20 may be the same as the materials and properties of the first layer 10 and the second layer 20 of FIG. 1. A thickness of the channel layer C10 may range from about 5 to about 300 nm, for example, from about 10 to about 200 nm. A thickness of the first layer 10 may range from about 5 to about 100 nm, and a thickness of the second layer 20 may range from about 5 to about 100 nm. However, thickness ranges of the first layer 10 and the second layer 20 and a total thickness range of the channel layer C10 may be changed.

The channel layer C10 may be deposited by using physical vapor deposition (PVD) such as sputtering, according to an example embodiment. The sputtering may be reactive sputtering. Also, the sputtering may be performed by using a single target or a plurality of targets. The single target or at least one of the plurality of targets may include zinc. Also, the single target and or at least one of the plurality of targets may further include another element, for example, fluorine, aluminum, gallium, or the like. During the sputtering, a nitrogen gas (N₂) and an oxygen gas (O₂) may be used as a reactive gas, and additionally, an argon (Ar) gas may be further used. When the first layer 10 and the second layer 20 are formed, used targets or composition of reactive gases may be different from each other. For example, a flow rate of an oxygen gas may be different, or sputtering power for a target including fluorine may be different. Due to such a change in a process condition, materials and properties of the first layer 10 and the second layer 20 may be different from each other.

The example method of forming the channel layer C10 may be changed in various example ways. For example, the channel layer C10 may be formed by using a method other than the sputtering, for example, metal organic chemical vapor deposition (MOCVD). Alternatively, the channel layer C10 may be formed by using another method such as chemical vapor deposition (CVD), atomic layer deposition (ALD), or evaporation.

Referring to FIG. 70, a source electrode S10 and a drain electrode D10 that respectively contact the first and second regions (for example, both ends) of the channel layer C10 may be formed on the gate insulating layer GI10, according to an example embodiment. The source electrode S10 may have a structure that contacts the first region (one end) and extends over a portion of the gate insulating layer GI10 that is adjacent to the first region. The drain region D10 may have a structure that contacts the second region (the other end) and extends over a portion of the gate insulating layer GI10 that is adjacent to the second region. A conductive film that covers the channel layer C10 may be formed on the gate insulating layer GI10, and then, the source electrode S10 and the drain electrode D10 may be formed by patterning (etching) the conductive film. Each of the source electrode S10 and the drain electrode D10 may be the same material layer as the gate electrode G10, or a material layer different from the gate electrode G10. Each of the source electrode S10 and the drain electrode D10 may be formed to have a single-layer structure or a multi-layer structure.

Referring to FIG. 7D, a passivation layer P10 that covers the channel layer C10, the source electrode S10, and the drain electrode D10 may be formed on the gate insulating layer GI10, according to an example embodiment. The passivation layer P10 may be formed of, for example, a silicon oxide layer, a silicon oxynitride layer, a silicon nitride layer, or an organic insulating layer, or a may be formed to have a structure in which at least two of a silicon oxide layer, a silicon oxynitride layer, a silicon nitride layer, and an organic insulating layer are stacked. A given annealing process may be performed before or after the passivation layer P10 is formed.

The example method of FIGS. 7A through 7D is an example method of manufacturing the transistor of FIG. 1. Each of the transistors of FIGS. 2 through 4 may be manufactured by using a modification of the method of FIGS. 7A through 7D. For example, the etch-stop layer ES10 (see FIG. 2) may be formed on the channel layer C10 in the operation of FIG. 7C, and then the source electrode S10 and the drain electrode D10 may be formed. In this case, the transistor of FIG. 2 may be manufactured. Whether to use the etch-stop layer ES10 may be determined according to a material of the channel layer C10 and materials of the source electrode S10 and the drain electrode D10. Alternatively, whether to use the etch-stop layer ES10 may be determined according to an etching process for forming the source electrode S10 and the drain electrode D10. Also, the transistor having a top gate structure as shown in FIG. 3 or 4 may be manufactured by inverting a stacked structure of a channel layer and forming a gate electrode above the channel layer. Besides, the method of FIGS. 7A through 7D may be changed in various ways.

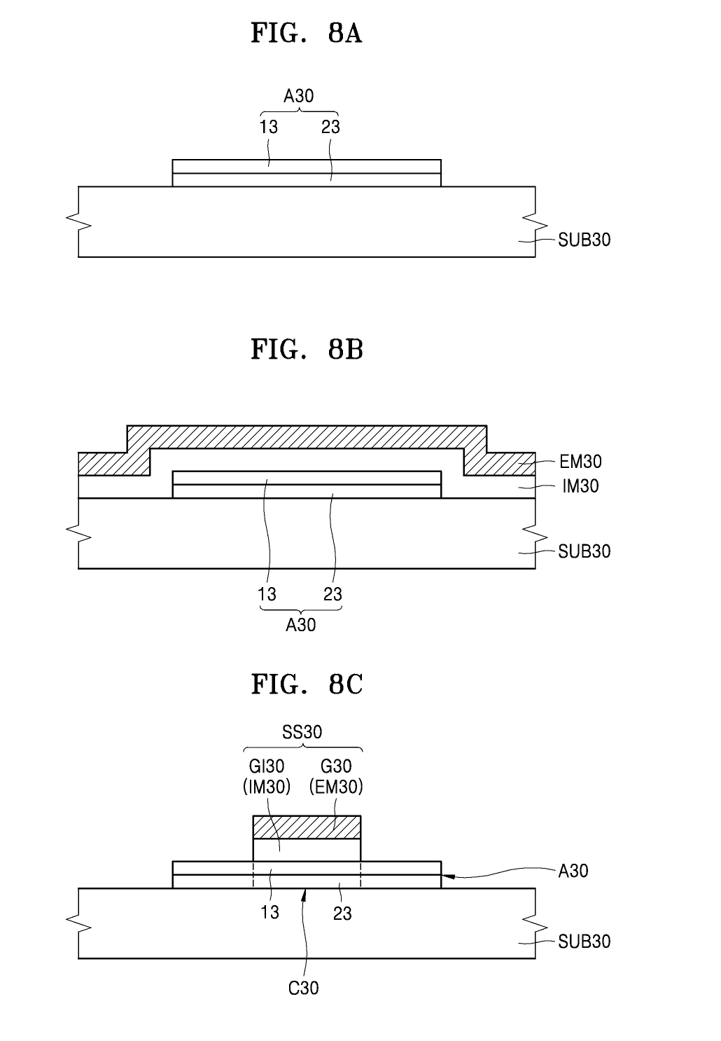

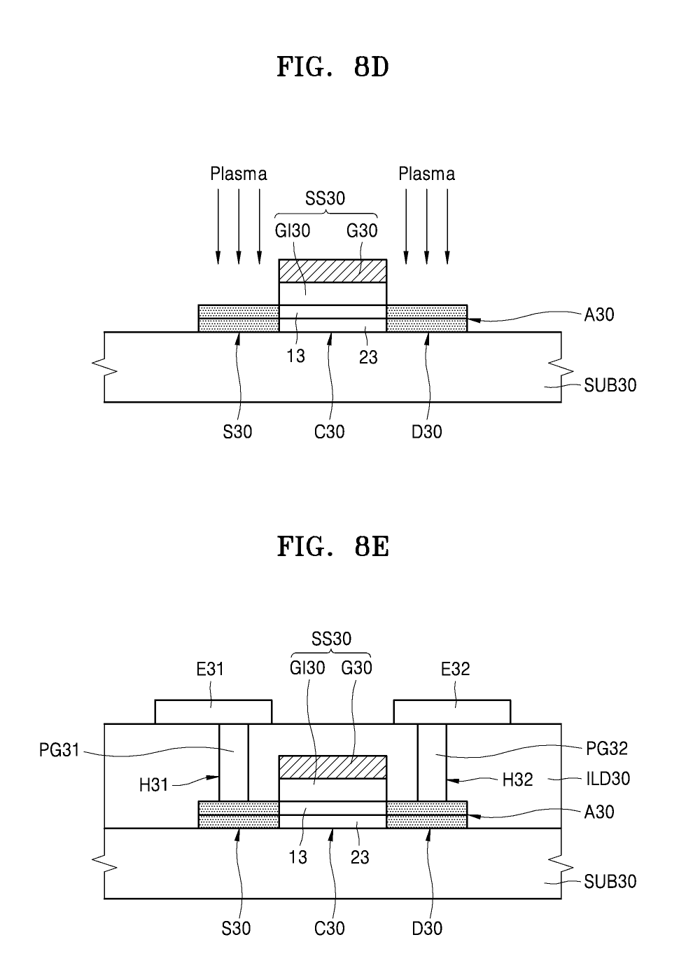

FIGS. 8A through 8E are cross-sectional views for explaining a method of manufacturing a transistor, according to another example embodiment. The method of FIGS. 8A through 8E is a method of manufacturing a TFT having a top gate structure.

Referring to FIG. 8A, an active layer A30 may be formed on a substrate SUB30, according to an example embodiment. The active layer A30 may be formed of a semiconductor, and may be formed to have a multi-layer structure including two or more layers. A method of forming the active layer A30 may be the same as the method of forming the channel layer C10 described with reference to FIG. 7B. However, the active layer A30 may be formed to have an inverted structure obtained by inverting the channel layer C10 or a structure similar to the inverted structure. That is, the active layer A30 may have a structure in which a second layer 23 and a first layer 13 are sequentially stacked from the bottom. Materials and properties of the first layer 13 and the second layer 23 may be the same as or similar to the materials and properties of the first layer 10 and the second layer 20 of FIG. 7B.

Referring to FIG. 8B, an insulating material layer IM30 that covers the active layer A30 may be formed on the substrate SUB30, according to an example embodiment. The insulating material layer IM30 may be formed of silicon oxide, silicon oxynitride, or silicon nitride, or may be formed of another material, for example, a high-k material having a dielectric constant higher than the dielectric constant of silicon nitride. The insulating material layer IM30 may be formed to have a structure in which at least two of a silicon oxide layer, a silicon oxynitride layer, a silicon nitride layer, and a high-k material layer are stacked. In detail, the insulating material layer IM30 may be formed of a silicon oxide layer, or may be formed to have a structure in which a silicon oxide layer and a silicon nitride layer are sequentially stacked, for example. Next, an electrode material layer EM30 may be formed on the insulating material layer IM30.

Next, as shown in FIG. 8C, a stacked structure SS30 may be formed at or around a central portion of the active layer A30 by sequentially etching the electrode material layer EM30 and the insulating material layer IM30, according to an example embodiment. A portion of the active layer A30 disposed under the stacked structure SS30 may be a channel region C30. In FIG. 8C, reference numeral GI30 denotes an etched insulating material layer (hereinafter, referred to as a gate insulating layer) and G30 denotes an etched electrode material layer (hereinafter, referred to as a gate electrode).

Referring to FIG. 8D, a source region S30 and a drain region D30 may be formed in the active layer A30 at both sides of the stacked structure SS30 by treating (processing) the active layer A30 at both sides of the stacked structure SS30 with plasma, according to an example embodiment. The plasma may be, for example, plasma of a gas including hydrogen (H). The gas including the hydrogen (H) may be NH₃, H₂, SiH₄, or the like. When both end portions of the active layer A30 are treated (processed) with the plasma of the gas including the hydrogen, the hydrogen may act as a carrier by entering the active layer A30. Also, the plasma of the hydrogen may remove an anion (oxygen or the like) of the active layer A30, and thus an electrical conductivity of a plasma-treated region may be increased. Thus, the source region S30 and the drain region D30 may each include a region whose anion (oxygen or the like) concentration is relatively low. In other words, the source region S30 and the drain region D30 may each include a region whose cation concentration is relatively high, for example, a zinc-rich region. The method of forming the source region S30 and the drain region D30 is an example, and may be changed in various ways.

Referring to FIG. 8E, an interlayer insulating layer ILD30 that covers the stacked structure SS30, the source region S30, and the drain region D30 may be formed on the substrate SUB30, according to an example embodiment. First and second contact holes H31 and H32 through which the source region S30 and the drain region D30 are exposed may be formed by etching the interlayer insulating layer ILD30, and a first conductive plug PG31 and a second conductive plug PG32 may be respectively formed in the first and second contact holes H31 and H32. Next, a first electrode E31 that contacts the first conductive plug PG31 and a second electrode E32 that contacts the second conductive plug PG32 may be formed on the interlayer insulating layer ILD30. Next, although not shown in FIG. 8E, a passivation layer that covers the first and second electrodes E31 and E32 may be further formed on the interlayer insulating layer ILD30. Annealing (i.e., performing heat treatment on) the substrate SUB30 at a desired (or, alternatively, predetermined) temperature in order to improve characteristics of the transistor may be further performed before or after the passivation layer is formed.

The example method of FIGS. 8A through 8E is an example method of manufacturing the transistor of FIG. 5. The transistor of FIG. 6 may be manufactured by using a modification of the method of FIGS. 8A through 8E. For example, the source/drain regions S30′ and D30′ of FIG. 6 may be formed by performing a first plasma treating on the active layer A30 at both sides of the stacked structure SS30 in the operation of FIG. 8D, forming an insulating spacer on both side walls of the stacked structure SS30, and performing a second plasma treating on the active layer A30 at both sides of the stacked structure SS30 and the insulating spacer. Next, the transistor as shown in FIG. 6 may be manufactured by performing a subsequent process. In addition, the method of FIGS. 8A through 8E may be modified in various ways.

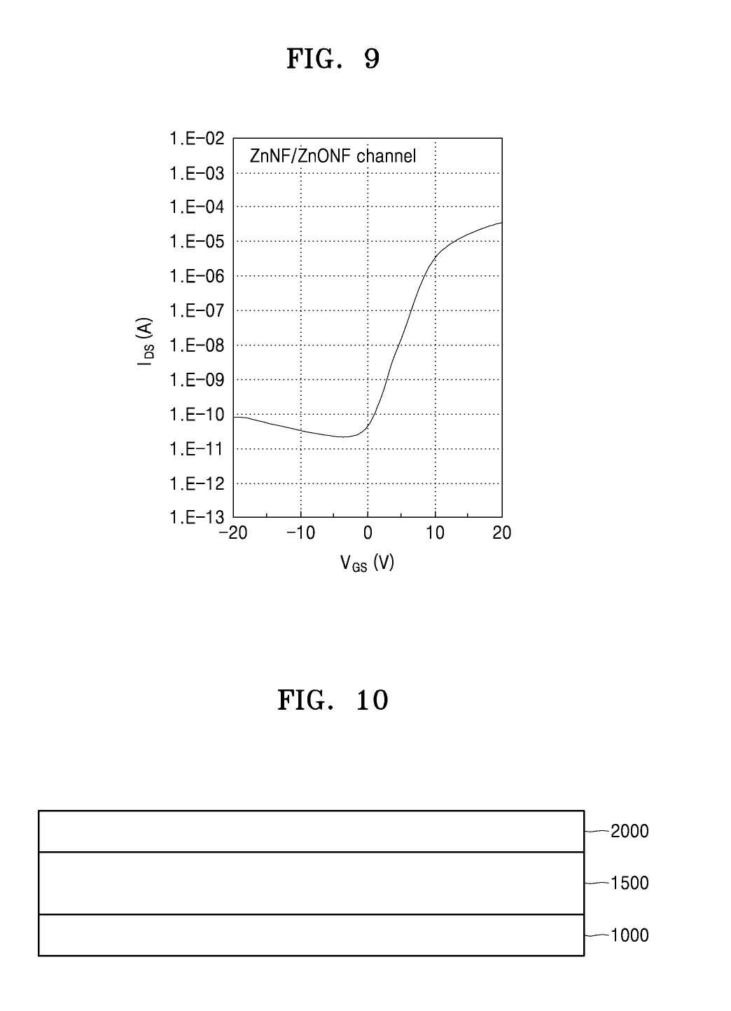

FIG. 9 is a graph illustrating transfer characteristics of a transistor including a channel layer having a multi-layer structure, according to an example embodiment. Transfer characteristics correspond to a relationship between a drain current I_{DS} and a gate voltage V_{GS}. FIG. 9 illustrates transfer characteristics of the transistor of FIG. 1. In this case, the first layer 10 of the channel layer C10 is a ZnNF layer, and the second layer 20 is a ZnONF layer.

Referring to FIG. 9, it is found that an ON current is greater than 10⁻⁵ A, an OFF current is lower than 10⁻¹⁰ A, and an ON/OFF current ratio is relatively high as about 10⁶. Accordingly, it is found that the transistor of FIG. 9 has a low OFF current, a high ON/OFF current ratio, and excellent characteristics. Also, it is found by measurement that a threshold voltage of the transistor is about 6.49 V that is relatively high. Also, it is found by measurement that a field-effect mobility of the transistor is about 25 cm²/Vs. Considering that when a mobility, that is, a field-effect mobility, of a transistor is equal to or greater than about 20 cm²/Vs, the transistor may be appropriately applied to a high-speed and high-resolution display apparatus, the transistor of FIG. 9 may be easily applied to a high-speed and high-performance electronic apparatus (display apparatus). Also, a field-effect mobility of the transistor may be increased to be equal to or greater than about 30 cm²/Vs or about 50 cm²/Vs by appropriately changing a material of a multi-layer channel. Accordingly, the transistor of the present example embodiment may be effectively used to realize a high-speed and high-resolution display apparatus.

Table 1 shows properties of a transistor according to an example embodiment and a comparative transistor. The transistor according to the example embodiment is the same as the transistor of FIG. 9. That is, the transistor according to the example embodiment has a structure of the transistor of FIG. 1, uses a ZnNF layer as the first layer 10 of the channel layer C10 and a ZnONF layer as the second layer 20 of the channel layer C10. The comparative transistor uses a channel layer having a single-layer structure formed of ZnNF.

TABLE 1

| | OFF current [A] | Threshold voltage [V] |
|---|---|---|
| Embodiment | 2.39E−11 | 6.49 |
| [ZnNF/ZnONF channel] | | |
| Comparative Example | 3.89E−11 | 1.15 |
| [ZnNF single-layer channel] | | |

Referring to Table 1, the comparative transistor has an OFF current that is about 1.6 times greater than an OFF current of the transistor according to an example embodiment. In other words, the transistor according to the example embodiment has a much lower OFF current than the comparative transistor. Meanwhile, a threshold voltage of the transistor according to the example embodiment is higher by about 5.3 V than a threshold voltage of the comparative transistor. Thus, it is found that according to the example embodiment, an OFF current of a transistor decreases and a threshold voltage thereof shifts in a positive (+) direction.

Transistors according to example embodiments may be applied as a switching device or a driving device to a display apparatus such as an organic light-emitting display apparatus or a liquid crystal display apparatus. As described above, since the transistor according to the example embodiment has a high mobility, a low OFF current, excellent switching characteristics (ON/OFF characteristics), and high reliability, the performance of a display apparatus may be improved when the transistor is applied to the display apparatus. Accordingly, the transistor according to the example embodiment may be effectively used to realize a next generation high-performance/high-resolution/large-size display apparatus. Also, the transistor according to the example embodiment may be applied for various purposes to other electronic devices such as a memory device or a logic device as well as a display apparatus. For example, the transistor according to the example embodiment may be used as a transistor constituting a peripheral circuit of a memory device or a selection transistor.

FIG. 10 is a cross-sectional view illustrating an electronic device including a transistor, according to an example embodiment. The electronic device of FIG. 10 is a display apparatus.

Referring to FIG. 10, an intermediate element layer 1500 may be disposed between a first substrate 1000 and a second substrate 2000, according to an example embodiment. The first substrate 1000 may be an array substrate including a transistor according to an example embodiment, for example, at least one of the transistors of FIGS. 1 through 6, as a switching device or a driving device. The second substrate 2000 may be a substrate facing the first substrate 1000. A configuration of the intermediate element layer 1500 may vary according to a type of the display apparatus. When the display apparatus is an organic light-emitting display apparatus, the intermediate element layer 1500 may include an “organic light-emitting layer”. When the display apparatus is a liquid crystal display apparatus, the intermediate element layer 1500 may include a “liquid crystal layer”. Also, when the display apparatus is a liquid crystal display apparatus, a backlight unit (not shown) may be further disposed under the first substrate 1000. A configuration of the electronic device including the transistor is not limited to that of FIG. 10, and may be modified in various ways.

While the example embodiments have been particularly shown and described, it will be understood by one of ordinary skill in the art that various changes in form and details may be made therein without departing from the spirit and scope of the example embodiments as defined by the following claims. For example, it will be understood by one of ordinary skill in the art that elements and structures of the transistors of FIGS. 1 through 6 may be modified in various ways. In detail, a channel layer may be formed to have a multi-layer structure including three or more layers, and in this case, an oxygen content or a fluorine content of each of a plurality of layers constituting the channel layer may increase farther away from a gate electrode. Alternatively, the channel layer may be a layer whose material and properties are gradually changed in a thickness direction and that has a single-layer structure. Also, the transistors according to the one or more example embodiments may each have a double-gate structure. The methods of FIGS. 7A through 7D and 8A through 8E may be changed in various ways. Also, the transistors according to the one or more example embodiments may be applied for various purposes to various electronic devices as well as to the display apparatus of FIG. 10. Accordingly, the scope of the example embodiments is defined not by the one or more embodiments but by the appended claims.

What is claimed is:

1. A transistor comprising:
a channel layer having a multi-layer structure;
a source and a drain respectively contacting first and second regions of the channel layer;
a gate corresponding to the channel layer; and
a gate insulating layer disposed between the channel layer and the gate,
wherein the channel layer comprises first and second layers,
wherein the first layer is disposed closer to the gate than the second layer,
wherein the first and second layers comprise a semiconductor material comprising zinc, oxygen, and nitrogen; and
wherein the second layer has an electrical resistance that is higher than an electrical resistance of the first layer.

2. The transistor of claim 1, wherein an oxygen content of the second layer is higher than an oxygen content of the first layer.

3. The transistor of claim 1, wherein the second layer further comprises fluorine, and the first layer does not include fluorine.

4. The transistor of claim 1, wherein
the first and second layers further comprise fluorine, and
a fluorine content of the second layer is higher than a fluorine content of the first layer.

5. The transistor of claim 1, wherein
at least one of the first and second layers further comprises an additional element X, and
the additional element X comprises at least one cation from among boron (B), aluminum (Al), gallium (Ga), indium (In), tin (Sn), titanium (Ti), zirconium (Zr), hafnium (Hf), and silicon (Si), at least one anion from among fluorine (F), chlorine (CI), bromine (Br), iodine (I), sulfur (S), and selenium (Se), or a combination thereof.

6. The transistor of claim 5, wherein a content of the additional element X of the first layer and a content of the additional element X of the second layer are different from each other.

7. The transistor of claim 5, wherein the additional element X included in the first layer and the additional element X included in the second layer are the same.

8. The transistor of claim 5, wherein the additional element X included in the first layer and the additional element X included in the second layer are different from each other.

9. The transistor of claim 1, wherein the second layer is configured to at least one of reduce an OFF current of the transistor and increase a threshold voltage of the transistor in a positive (+) direction.

10. The transistor of claim 1, wherein the gate is disposed below the channel layer.

11. The transistor of claim 10, wherein the transistor further comprises an etch-stop layer disposed on the channel layer.

12. The transistor of claim 1, wherein the gate is disposed above the channel layer.

13. A display apparatus comprising the transistor of claim 1.

14. A transistor comprising:
a channel layer having a multi-layer structure;
a source and a drain respectively contacting first and second regions of the channel layer;
a gate corresponding to the channel layer; and
a gate insulating layer disposed between the channel layer and the gate,
wherein the channel layer comprises first and second layers,
wherein the first layer is disposed closer to the gate than the second layer;
wherein at least one of the first and second layers is formed of a semiconductor material comprising zinc fluoronitride, and
wherein the second layer has an electrical resistance that is higher than an electrical resistance of the first layer.

15. The transistor of claim 14, wherein
the first layer comprises zinc fluoronitride, and
the second layer comprises one of zinc oxide, zinc oxynitride, and zinc fluorooxynitride.

16. The transistor of claim 14, wherein
both the first and second layers comprise zinc fluoronitride, and
a fluorine content of the second layer is higher than a fluorine content of the first layer.

17. The transistor of claim 14, wherein an oxygen content of the second layer is higher than an oxygen content of the first layer.

18. The transistor of claim 14, wherein
at least one of the first and second layers further comprises an additional element X, and
the additional element X comprises at least one cation from among boron (B), aluminum (Al), gallium (Ga), indium (In), tin (Sn), titanium (Ti), zirconium (Zr), hafnium (Hf), and silicon (Si), at least one anion from among fluorine (F), chlorine (CI), bromine (Br), iodine (I), sulfur (S), and selenium (Se), or a combination thereof.

19. The transistor of claim 18, wherein a content of the additional element X of the first layer and a content of the additional element X of the second layer are different from each other.

20. The transistor of claim 18, wherein the additional element X included in the first layer and the additional element X included in the second layer are the same.

21. The transistor of claim 18, wherein the additional element X included in the first layer and the additional element X included in the second layer are different from each other.

22. The transistor of claim 14, wherein the second layer is configured to at least one of reduce an OFF current of the transistor and increase a threshold voltage of the transistor in a positive (+) direction.

23. The transistor of claim 14, wherein the gate is disposed below the channel layer.

24. The transistor of claim 23, wherein the transistor further comprises an etch-stop layer disposed on the channel layer.

25. The transistor of claim 14, wherein the gate is disposed above the channel layer.

26. A display apparatus comprising the transistor of claim 14.
